(19) United States
(12) Patent Application Publication
(10) Pub. No.: US 2003/0205363 A1
(43) Pub. Date: Nov. 6, 2003

(54) Enhanced air cooling of electronic devices using fluid phase change heat transfer

(75) Inventors: Richard C. Chu, Hopewell Junction, NY (US); Michael J. Ellsworth JR., Lagrangeville, NY (US); Robert E. Simons, Poughkeepsie, NY (US)

Correspondence Address: Andrew J. Wojnicki, Jr., IBM Corporation - M/S P386, 2455 South Road, Poughkeepsie, NY, 12601, US

(73) Assignee: International Business Machines Corporation, Armonk, NY (US)

(21) Appl. No.: 10/040,680

(22) Filed: Nov. 9, 2001

(51) Int. Cl. F28F 7/00; F28D 15/00; H05K 7/20

(52) U.S. Cl. 165/80.3; 165/104.33; 361/700; 257/715

(57) ABSTRACT

A cooling apparatus for an electronic module, to enhance air cooling of electronic devices using a closed loop, phase change fluid heat transfer mechanism to transfer thermal energy from electronic devices to air cooled fins. The evaporator includes a surface for making thermal contact with an electronic module to be cooled. The boiling chamber is disposed within the evaporator, and includes a plurality of fluid inlet ports disposed near one end, and a plurality of fluid outlet ports disposed near an opposite end. The condenser includes a plurality of tubes and a plurality of thermally conductive fins. Each tube is in fluid flow communication with one fluid inlet port and one fluid outlet port, forming a fluid flow path. Each fin is in thermal contact with one or more tubes. A check valve is disposed within each fluid flow path proximate an inlet port.

### CROSS REFERENCE TO RELATED APPLICATIONS

This application contains subject matter which is related to the subject matter of the following applications, each of which is assigned to the same assignee as this application and each of which is hereby incorporated herein by reference in its entirety:

“Electronic Device Substrate Assembly with Impermeable Barrier and Method of Making,” Chu et al., having attorney Docket No. POU920010135US1, Ser. No. ______, co-filed herewith.

### FIELD OF THE INVENTION

The present invention relates in general to a cooling apparatus for an electronic module. In particular, the present invention relates to an apparatus to enhance air cooling of electronic devices using a closed loop, phase change fluid heat transfer mechanism to transfer thermal energy from electronic devices to air cooled fins.

### BACKGROUND OF THE INVENTION

As is known, operating electronic devices produce heat. This heat should be removed from the devices in order to maintain device junction temperatures within desirable limits: failure to remove the heat thus produced results in increased device temperatures, potentially leading to thermal runaway conditions. Several trends in the electronics industry have combined to increase the importance of thermal management, including heat removal for electronic devices, including technologies where thermal management has traditionally been less of a concern, such as CMOS. In particular, the need for faster and more densely packed circuits has had a direct impact on the importance of thermal management. First, power dissipation, and therefore heat production, increases as the device operating frequencies increase. Second, increased operating frequencies may be possible at lower device junction temperatures. Finally, as more and more devices are packed onto a single chip, power density (Watts/cm²) increases, resulting in the need to remove more power from a given size chip or module. These trends have combined to create applications where it is no longer desirable to remove the heat from modern devices solely by traditional air cooling methods, such as by using traditional air cooled heat sinks.

While alternatives to air cooling are known, such as chilled water and refrigeration systems, these alternatives tend to increase both manufacturing and operational costs, and therefore tend to be applied primarily in high performance applications. Methods are therefore desirable which augment traditional air cooling methods, thereby overcoming at least some of the limitations of traditional methods, without introducing costly refrigeration or chilled water distribution systems.

Traditional methods of air cooling electronic devices, such as the use of air cooled heatsinks, involve two or more heat transfer processes. Heat is first transferred from the electronic device to the heatsink fins, and then from the heatsink fins to the ambient air. The overall efficiency of the heatsink may be improved by improving either transfer process, or both.

With respect to the transfer of heat from the device to the heatsink fins, several parameters tend to determine the rate of heat transfer: a) the thermal conductivity of the interface between device and heatsink, b) thermal conductivity of the heatsink fins, and c) the temperature differential between the device and the fins. In addition to the temperature differential between the device and the portion of the fins closest to the device (fin base), a temperature differential exists between the fin base and the portion of the fins furthest from the device (fin tip). This temperature differential drives heat transfer from the fin base to the fin tip, through a fin material having finite thermal conductivity.

With respect to the transfer of heat from the heatsink fins to the ambient air, several parameters may be changed to improve the efficiency of this transfer. In particular, the heat transferred from the fins to the ambient air is a function of a) the temperature differential between the fins and the ambient air, b) the rate at which air flows through the fins, and c) the total fin surface area. While, in general, an increase in any of these factors tends to improve the efficiency with which heat transfers from fins to ambient, design considerations may place practical limitations on the extent to which any parameter may be increased, and interactions between the various parameters may limit the effectiveness of a particular parameter change. For example, many electronic applications are constrained to occupy a limited volume or footprint (i.e. floor surface area). Increases in fin surface area, therefore, are likely accomplished by decreasing fin thickness and increasing fin density, effectively increasing fin surface area within a constant heatsink volume. As fin density thus increases, however, so does the pressure differential between airflow entering the fins and airflow leaving the fins. Both airflow rates and pressure drops are frequently limited by other design considerations, such as acoustic constraints.

Another method of increasing fin surface area involves extending the length of the fins, or the distance which the fins extend from the electronic device. Extending the fin length is likely to result in an increase in the overall module volume. Furthermore, extending fin length is also likely to reach a practical limit as a result of the temperature differential along the length of each fin. This phenomenon is known as fin efficiency.

Fin efficiency places practical limitations upon the extent to which air cooling may be improved solely by increasing the length of cooling fins. As previously noted, two heat transfer processes occur in a traditional fin heatsink. Each transfer process is driven by a temperature differential. Reduced fin efficiency, briefly stated, results when the temperature differential driving one heat transfer process (from device to fins) reduces at least some portion of the temperature differential driving the other heat transfer process (from fins to ambient). In particular, the fin-to-ambient heat transfer process is driven by the temperature differential between the fin and the ambient. Assuming a constant ambient temperature along the length of a fin, the greatest fin-ambient temperature differential occurs at the fin base, where the fin temperature is highest. The maximum or ideal fin-to-ambient heat transfer, therefore, would occur if the fin temperature along the entire fin length equaled the fin base temperature. As previously noted, however, heat transfer from fin base to fin tip is driven by a temperature differential between the fin base and fin tip: a temperature gradient therefore exists along the length of the fin. Since an incremental fin area near the tip is therefore at a lower temperature than an equivalent area near the fin base, the fin tip-to-ambient temperature differential is less than the fin base-to-ambient temperature differential. Since the temperature differential, which drives heat transfer, is lower at the fin tip, less heat is transferred by an area at the fin tip than by an equal area at the fin base.

Fin efficiency limitations may be partially overcome by providing a mechanism capable of transferring heat from a device to the cooling fins, without relying primarily on conduction through the fin material. Such a mechanism should preferably reduce the temperature differential between any two points on the fins. Three such mechanisms are known in the art: heat pipes, thermosyphons, and closed loop phase change (evaporator/condenser) systems.

For example, U.S. Pat. Nos. 5,925,929, entitled “Cooling Apparatus for Electronic Elements,” and 5,986,882, entitled “Electronic Apparatus having Removable Processor/Heat Pipe Cooing Device Modules Therein,” describe the use of heat pipes to transfer heat from an electronic device to cooling fins. U.S. Pat. Nos. 6,223,810, entitled “Extended Air Cooling with Heat Loop for Dense or Compact Configurations of Electronic Components,” and 5,953,930, entitled “Evaporator for Use in an Extended Air Cooling System for Electronic Components,” and pending U.S. patent application Ser. No. 09/736,455, entitled “Extended Air Cooling with Heat Loop for Dense or Compact Configurations of Electronic Components,” describe the use of a thermosyphon or heat loop device to move heat from electronic devices to an air cooled heat exchanger some distance from the devices. This approach is most useful in applications having densely packed electronics which are located some distance from a cooling airflow, and where system design constraints can accommodate the heat transfer mechanism. Also for example, U.S. Pat. Nos. 5,647,430, entitled “Electronic Component Cooling Unit,” and 5,998,863, entitled “Cooling Apparatus Boiling and Condensing Refrigerant,” disclose closed loop phase change systems, wherein a refrigerant is used to transfer heat from an electronic device to cooling fins.

As illustrated in FIG. 1, air cooling may be used to cool an entire electronics system. A typical electronics cabinet 70 is illustrated in FIG. 1, showing air flowing from inlet 72, over cards 74, over modules 78 mounted on board 76, through power compartment 80, driven by blowers 82a and 82b, finally exiting cabinet 70 through exhaust outlet 84. The arrangement of FIG. 1 has the advantage that a single set of blowers 82a and 82b provide cooling airflow to the entire system 70. Modules 78 are preferably located within the cooling airflow as illustrated in FIG. 1, and oriented in a manner enabling efficient cooling in such an arrangement, such as by orienting modules 78 vertically.

For the foregoing reasons, therefore, there is a need in the art for an electronic module apparatus capable of being cooled by airflow, which employs an enhanced method of transferring heat from device to cooling fins, and which is capable of efficient operation when the module is placed directly within the cooling airflow, and the module is oriented vertically.

### SUMMARY

The present invention is directed to an electronic module apparatus capable of being cooled by airflow, which employs an enhanced method of transferring heat from device to cooling fins, and which is capable of efficient operation when the module is oriented vertically and placed directly within the cooling airflow.

In one aspect of the present invention, an electronic module cooling assembly is disclosed, including an evaporator, a boiling chamber within the evaporator, a condenser, and a plurality of check valves. The evaporator includes a surface for making thermal contact with an electronic module to be cooled. The boiling chamber is disposed within the evaporator, and includes a plurality of fluid inlet ports disposed near one end, and a plurality of fluid outlet ports disposed near an opposite end. The condenser includes a plurality of tubes and a plurality of thermally conductive fins. Each tube is in fluid flow communication with one fluid inlet port and one fluid outlet port, forming a fluid flow path. Each fin is in thermal contact with one or more tubes. A check valve is disposed within each fluid flow path proximate an inlet port, each check valve allowing fluid flow from a tube to the boiling chamber, while preventing fluid flow from the boiling chamber to the tube.

In another aspect of the present invention, a cooled electronic module assembly is disclosed, including an electronic module, an evaporator, a boiling chamber within the evaporator, a condenser, and a plurality of check valves. The evaporator is in thermal contact with the electronic module. The boiling chamber is disposed within the evaporator, and includes a plurality of fluid inlet ports disposed near one end, and a plurality of fluid outlet ports disposed near an opposite end. The condenser includes a plurality of tubes and a plurality of thermally conductive fins. Each tube is in fluid flow communication with one fluid inlet port and one fluid outlet port, forming a fluid flow path. Each fin is in thermal contact with one or more tubes. A check valve is disposed within each fluid flow path proximate an inlet port, each check valve allowing fluid flow from a tube to the boiling chamber, while preventing fluid flow from the boiling chamber to the tube.

In yet another aspect of the present invention, an electronic module cooling assembly is disclosed, including an evaporator, a boiling chamber within the evaporator, a condenser, a plurality of check valves, an air moving device, and a plurality of baffles. The evaporator includes a surface for making thermal contact with an electronic module to be cooled. The boiling chamber is disposed within the evaporator, and includes a plurality of fluid inlet ports disposed near one end, and a plurality of fluid outlet ports disposed near an opposite end. The condenser includes a plurality of tubes and a plurality of thermally conductive fins. Each tube is in fluid flow communication with one fluid inlet port and one fluid outlet port, forming a fluid flow path. Each fin is in thermal contact with one or more tubes. A check valve is disposed within each fluid flow path proximate an inlet port, each check valve allowing fluid flow from a tube to the boiling chamber, while preventing fluid flow from the boiling chamber to the tube. The air moving device is disposed such that it is capable of causing air to flow through the condenser. The baffles are positioned to direct airflow through the condenser.

It is therefore an object of the present invention to provide enhanced air cooling of electronic devices by improving the transfer of heat from an electronic device to a plurality of cooling fins. It is a further object of the present invention to provide such a device that is capable of efficient operation when the module is oriented vertically and placed directly within the cooling airflow.

The recitation herein of a list of desirable objects which are met by various embodiments of the present invention is not meant to imply or suggest that any or all of these objects are present as essential features, either individually or collectively, in the most general embodiment of the present invention or in any of its more specific embodiments.

### BRIEF DESCRIPTION OF THE DRAWINGS

The subject matter which is regarded as the invention is particularly pointed out and distinctly claimed in the concluding portion of the specification. The invention, however, both as to organization and method of practice, together with further objects and advantages thereof, may best be understood by reference to the following description taken in connection with the accompanying drawings in which:

FIG. 1 depicts a side view of an air cooled electronics enclosure;

FIG. 2A depicts a field replaceable cooling unit attached to a module to be cooled, per an embodiment of the present invention;

FIG. 2B depicts a field replaceable cooling unit, per an embodiment of the present invention;

FIG. 3 depicts a field replaceable cooling unit employing optional performance enhancements, per an embodiment of the present invention;

FIG. 4A depicts a check valve during normal fluid flow, per an embodiment of the present invention;

FIG. 4B depicts a check valve preventing backflow, per an embodiment of the present invention;

FIG. 5A depicts a top view of an evaporator per an embodiment of the present invention, illustrating placement of a filling valve;

FIG. 5B depicts a filling valve as shown in FIG. 5A, per an embodiment of the present invention;

FIG. 5C depicts the filling valve of FIG. 5B during introduction of cooling fluid, per an embodiment of the present invention;

FIG. 5C depicts the filling valve of FIG. 5B after sealing, per an embodiment of the present invention;

FIG. 6 depicts an integrated cooling unit and electronic module, per an embodiment of the present invention;

FIG. 7 depicts an integrated cooling unit with slanted condenser tubes, and electronic module, per an embodiment of the present invention;

FIG. 8 depicts an alternative integrated cooling unit and electronic module, per an embodiment of the present invention;

FIG. 9A depicts a cross section of a cooling subassembly per an embodiment of the present invention, taken along line A-A of FIG. 9B;

FIG. 9B depicts a cross section of the cooling subassembly illustrated in FIG. 9A, taken along line B-B;

FIG. 10A depicts a side cross sectional view of an environment within which embodiments of the present invention may be used, taken along line C-C of FIG. 10B;

FIG. 10B depicts a side cross sectional view of the environment illustrated in FIG. 10A, taken along line D-D;

FIG. 10C depicts a top view of the environment illustrated in FIG. 10A, taken along line E-E; and

FIG. 11 depicts a side view of an air cooled electronics enclosure including one or more embodiments of the present invention.

### DETAILED DESCRIPTION OF THE INVENTION

In accordance with preferred embodiments of the present invention, provided herein is an electronic module cooling assembly. The cooling assembly includes an evaporator, a boiling chamber, a condenser, and a plurality of check valves. The evaporator includes a surface for making thermal contact with an electronic module to be cooled. The boiling chamber is disposed within the evaporator, and includes a plurality of fluid inlet ports disposed near one end, and a plurality of fluid outlet ports disposed near an opposite end. The condenser includes a plurality of tubes and a plurality of thermally conductive fins. Each tube is in fluid flow communication with one fluid inlet port and one fluid outlet port, forming a fluid flow path. Each fin is in thermal contact with one or more tubes. A check valve is disposed within each fluid flow path proximate an inlet port, each check valve allowing fluid flow from a tube to the boiling chamber, while preventing fluid flow from the boiling chamber to the tube. The cooling assembly may be separable from the module to be cooled in order to facilitate field servicing, or the cooling assembly may be an integral part of an electronic module. Furthermore, the separable cooling assembly or the cooled module may be part of a larger cooling assembly including an air moving device and airflow baffles.

Environment

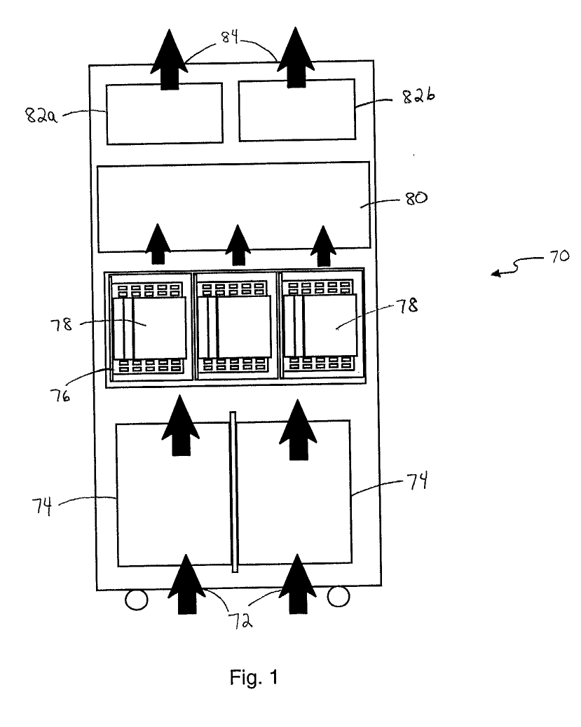

FIG. 1 illustrates a typical air cooled electronics enclosure environment. Enclosure 70 contains a variety of electronic devices, all cooled by airflow created by one or more air moving devices 82a and/or 82b. In the exemplary environment of FIG. 1, electronic devices include cards 74, high power modules 78 mounted on boards 76, and power devices within compartment 80. In the environment illustrated in FIG. 1, it is desirable for high power modules 78 to be oriented vertically, allowing continuous flow of air from inlet 72, located at the bottom of enclosure 70, over cards 74, modules 78, compartment 80, to exhaust 84 located at the top of enclosure 70.

Field Replaceable Cooling Unit

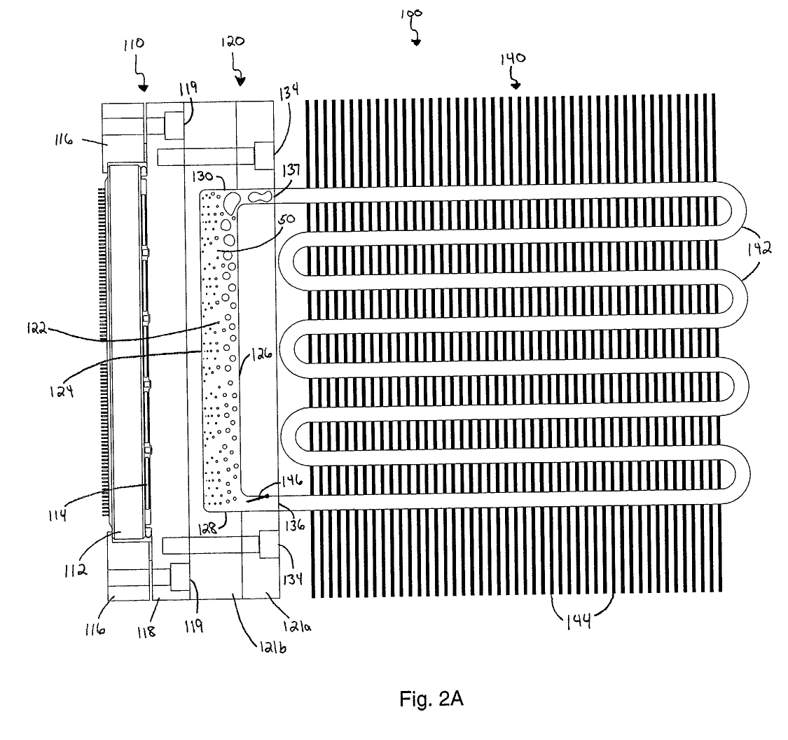

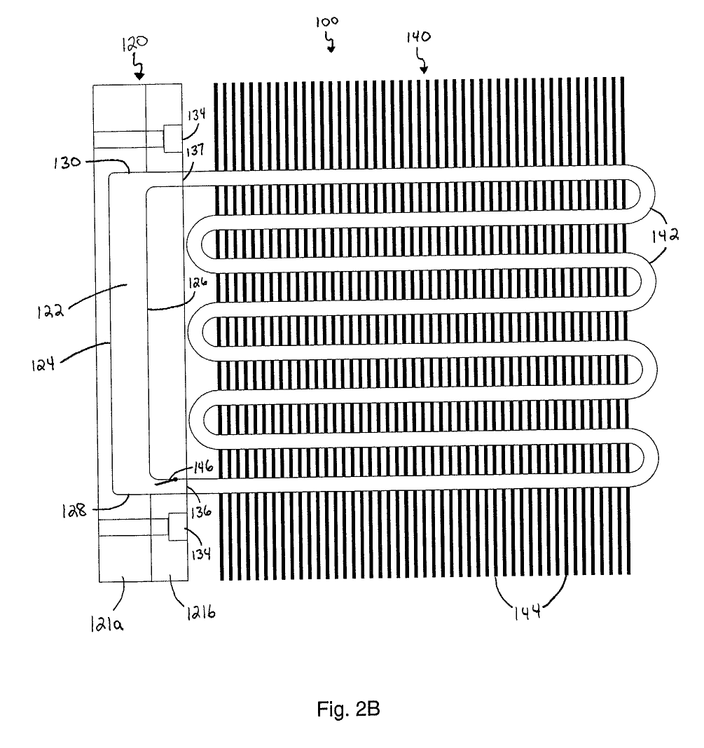

FIGS. 2A and 2B illustrate an embodiment of the present invention, removable cooling assembly 100. FIG. 2A illustrates assembly 100 in relation to electronic module assembly 110. Module 110 includes substrate 112, to which devices 114 are electrically connected, a base plate 116, module hat 118, and connectors 119. As depicted in FIG. 2A, connectors 119 connect module hat 118 to base plate 116. Base plate 116 holds substrate 112; connectors 119 therefore compress substrate 112 and devices 114 against module hat 118. Devices 114 are thus in thermal contact with hat 118. The thermal interface between devices 114 and hat 118 may be enhanced using a thermal grease, paste, or oil as known in the art. As shown in FIG. 2A, cooling assembly 100 is connected to hat 118 by connectors 134, thus placing the upper surface of hat 118 and the lower surface of evaporator 120 in thermal contact.

FIGS. 2A and 2B illustrate further details of cooling assembly 100. FIG. 2A depicts assembly 100 attached to module 110 by connectors 134. FIG. 2B depicts cooling assembly 100 as a field replaceable unit, separate from module 110. The following features are illustrated in both FIGS. 2A and 2B. Cooling assembly 100 includes two sections: evaporator 120 and condenser 140. Evaporator 120 and condenser 140 are in fluid flow communication, as described in detail herein. Evaporator 120 is comprised of two portions, boiling chamber portion 121a and cover 121b, which are sealably bonded together to form evaporator 120. Evaporator 120 contains a boiling chamber 122, capable of containing a cooling fluid. Boiling chamber 122 includes boiling surface 124, the surface closest to the thermal interface between evaporator 122 and hat 118. Boiling chamber 122 further includes surface 126 opposite boiling surface 124, bottom surface 128, and top surface 130. In the embodiment of FIG. 2, the edges of and transitions between boiling chamber surfaces are curved or rounded, in order to prevent entrapment of vapor. Proximate surfaces 126 and 128 is fluid inlet port 136. Proximate surfaces 126 and 130 is fluid outlet port 137. Check valve 146 is disposed proximate fluid inlet port 136. Condenser 140 includes tube 142 and a plurality of fins 144. Fins 144 are thermally coupled to tube 142. Tube 142 is in fluid flow communication with fluid inlet port 136 and fluid outlet port 137. Tube 142 is sealably connected to evaporator 120 at ports 136 and 137: this connection creates the mechanical, thermal, and fluid flow connections between evaporator 120 and condenser 140.

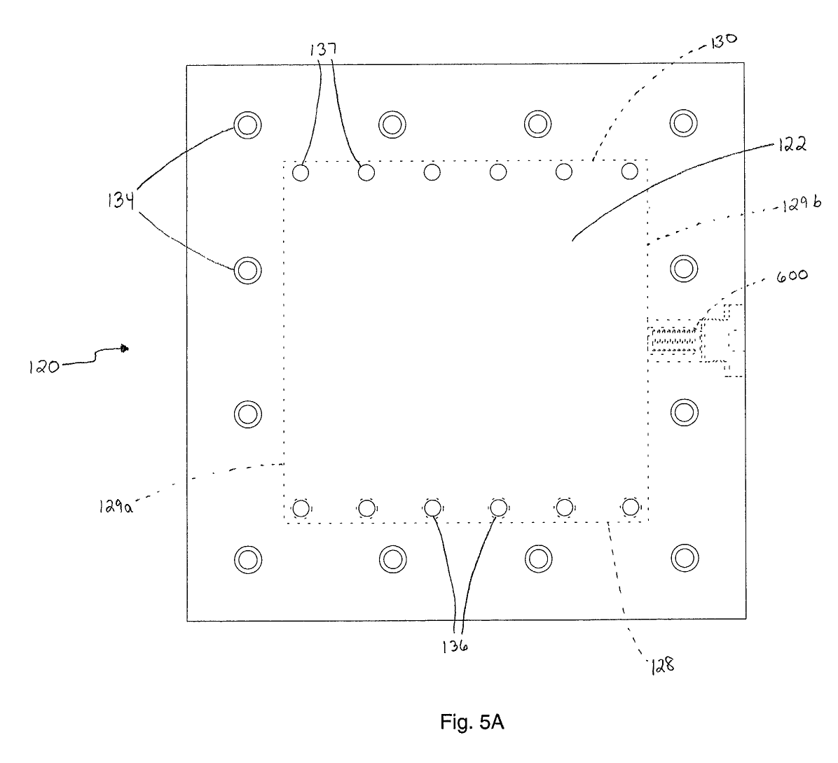

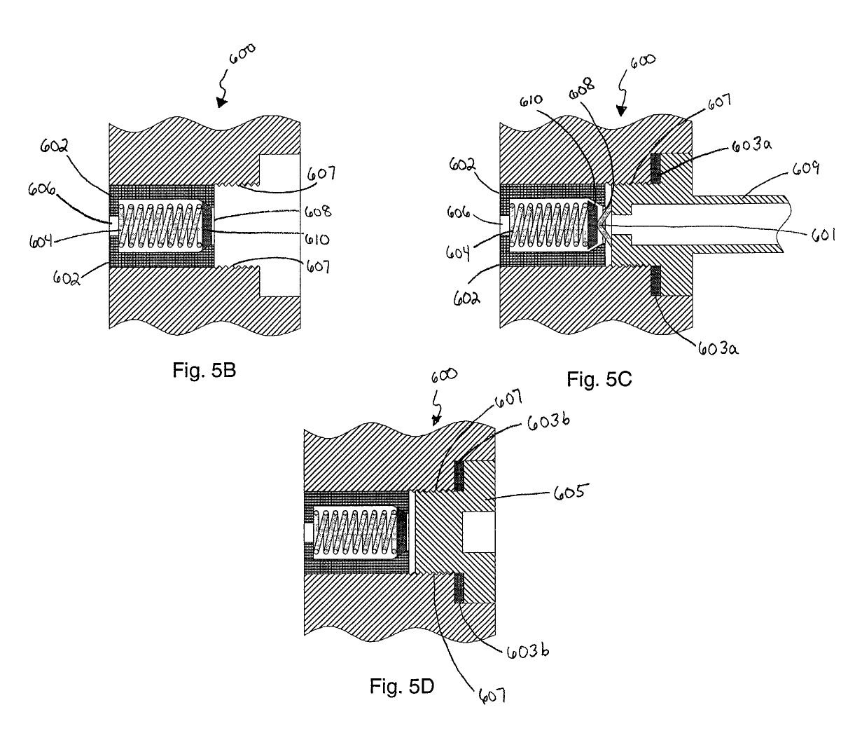

Additional details of evaporator 120 are illustrated in FIG. 5A. FIG. 5A depicts a top view of evaporator 120, without condenser 140. Evaporator 120 includes a plurality of connectors 134 disposed around a periphery of evaporator 120. FIG. 5A illustrates 12 connectors 134; more or fewer connectors 134 may be used, within the spirit and scope of the present invention. Evaporator 120 also includes a plurality of fluid inlet ports 136, and a plurality of fluid outlet ports 137. Each fluid outlet port is connected to one fluid inlet port by one tube 142 (visible in FIGS. 2A and 2B). FIG. 5A illustrates six inlet/outlet port pairs; more or fewer inlet/outlet port pairs may be used, within the spirit and scope of the present invention. FIG. 5A further illustrates the position of boiling chamber 122 within evaporator 120. Boiling chamber 122 is defined by top and bottom surfaces 130 and 128, respectively, both of which are visible in FIGS. 2A and 2B, and side surfaces 129a and 129b, which are not visible in FIGS. 2A and 2B. Finally, FIG. 5A depicts valve 600, the purpose and operation of which is described in detail herein.

With reference now to FIG. 2A, the operation of cooling assembly 100 is described. As illustrated in FIG. 2A, cooling assembly 100 is mechanically and thermally coupled to module 110. This coupling is accomplished by connecting evaporator 120 to module hat 118, using connectors 134. Heat produced by devices 114 is conducted across the interface between devices 114 and hat 118, through hat 118, across the interface between hat 118 and evaporator 120, ultimately reaching boiling surface 124. FIG. 2A further depicts a cooling fluid 50 disposed within boiling chamber 122 and in thermal contact with boiling surface 124. Heat is transferred from evaporator 120 to fluid 50 at boiling surface 124, causing fluid 50 to boil. Fluid 50 vapor, which is less dense than fluid 50 liquid, rises toward boiling chamber top surface 130. As previously noted, fluid outlet port 137 is disposed proximate top surface 130. Rising fluid 50 vapors accumulate near outlet port 137, then exit boiling chamber 122 through outlet port 137, and enter condenser 140 through tube 142. Condenser 140 is a liquid to air heat exchanger. Fluid 50 enters condenser 140 as a hot vapor. Heat from fluid 50 is transferred to tubes 142, then to cooling fins 144. Cooling fins 144 transfer heat to the ambient air. By thus transferring heat from fluid 50 vapor to the ambient air, condenser 140 removes heat from fluid 50 vapor, eventually causing fluid 50 to condense back to a liquid state. Fluid 50, now liquid or condensate, continues to flow through tube 142, driven by gravity, eventually returning to boiling chamber 122 through inlet port 136 and check valve 146. Check valve 146 allows fluid 50 to flow from tube 142 into the bottom portion of boiling chamber 122, but does not allow fluid 50 to flow from the bottom portion of boiling chamber 122 into tube 142. Check valve 146 therefore enables boiling chamber 122 to remain filled with fluid 50 in a liquid state, at a level above the condensate level within tube 142, as described in further detail herein. Assembly 100 therefore provides a closed loop, phase change fluid flow path, using fluid 50 to transfer heat from boiling surface 124 to fins 144, without relying on thermal conduction through the fin material.

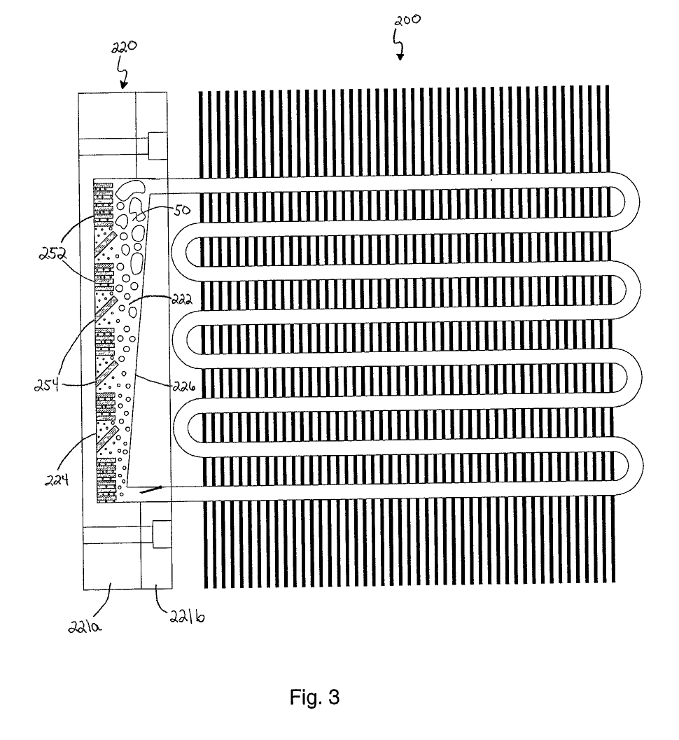

While not required in the most general embodiments of the present invention, a number of optional performance enhancements may be added to the embodiment illustrated in FIG. 2, resulting in a number of alternative embodiments within the spirit and scope of the present invention. The embodiment of FIG. 3, cooling apparatus 200, illustrates three such enhancements: extended heat transfer surfaces 252, vapor deflectors 254, and divergent boiling chamber 222. When used, extended heat transfer surfaces 252 are placed in thermal contact with boiling surface 224, effectively increasing the surface area of boiling surface 224. Surfaces 252 therefore increase the contact area for thermal transfer between fluid 50 and boiling surface 224, improving the rate of heat transfer to fluid 50. Surfaces 252 may be used with or without vapor deflectors 254. While extended surfaces 252 are preferably oriented to minimize interference with rising vapor, such as by orienting the surfaces vertically, the possibility still exists for rising vapors to be trapped or slowed by extended heat transfer surfaces 252. By placing a vapor deflector 254 below each extended surface 252, and angling vapor deflector 254 to deflect rising vapors from the extended surfaces as shown in FIG. 3, vapors continue to rise toward the top of boiling chamber 222. Since trapped vapors reduce the effective thermal transfer area between boiling surface 224 and fluid 50, preventing vapors from becoming trapped within and below surfaces 252 further improves heat transfer from boiling surface 224 to fluid 50.

Another optional performance enhancement illustrated in the embodiment of FIG. 3, divergent boiling chamber 222, also limits vapor entrapment. In the embodiment illustrated in FIG. 2, surface 126 is substantially parallel to boiling surface 124. As previously noted, the edges of and transitions between boiling chamber surfaces are curved or rounded to prevent entrapment of vapor. As an alternative to rounded edges, divergent boiling chamber 222 employs a surface 226 which diverges from boiling surface 224 along the direction of vapor flow: the distance between surfaces 226 and 224 is greater near the top of boiling chamber 222 than at the bottom of boiling chamber 222. By providing an increased volume near the top of boiling chamber 222, vapor is prevented from becoming entrapped within boiling chamber 222, where vapor could impede the transfer of heat from boiling surface 224 to a fluid within boiling chamber 222.

Vertical Module Orientation

As noted in FIG. 1, in some applications it is desirable to orient an electronic module vertically, while supplying a cooling airflow over the surface of a heatsink or heat exchanger attached to the module. The present invention is particularly adapted to perform when attached to a vertically oriented module, as well as when attached to a module that is oriented substantially vertically (i.e. somewhat tilted with respect to vertical). As seen in FIG. 2, the primary features of the present invention enabling vertical operation are: placement of fluid inlet 136 and outlet 137, design of tube 142, and check valve 146. These features are described in detail herein.

As illustrated in FIG. 2A, fluid flow within the closed loop path from boiling chamber 122 to tube 142 and back to boiling chamber 122 is driven by gravity. Within boiling chamber 122, fluid 50, in liquid state, boils creating fluid 50 vapor. Fluid 50 vapor, less dense than fluid 50 in its liquid state, rises toward the top of boiling chamber 122, where outlet port 137 is located. Within boiling chamber 122, therefore, gravity causes the heavier liquid to remain, while enabling the lighter vapor to gather near outlet port 137, thereby exiting boiling chamber 122. The opposite occurs within condenser 140. As condenser 140 removes heat from fluid 50 vapor, fluid 50 vapor eventually condenses into fluid 50 liquid, or condensate. Since fluid 50 liquid is more dense than fluid 50 vapor, fluid 50 liquid tends to flow through the tubes 142 of condenser 140, accumulating in the bottom-most portions of tubes 142, eventually returning to boiling chamber 122 through inlet port 136. Within condenser 140, therefore, gravity causes the less dense vapor to remain, while allowing the more dense liquid to exit.

With further reference to FIG. 2A, check valve 146 provides a mechanism to temper the effects of gravity, enabling more efficient operation of evaporator 120 and condenser 140. As previously noted, embodiments of the present invention employ a phase change fluid flow system to transfer heat from module 110 to condenser 140. The two main portions of cooling assembly 100, evaporator 120 and condenser 140, drive complimentary phase changes in a cooling fluid within assembly 100. Evaporator 120 transfers heat to the cooling fluid, causing it to boil, thereby causing a change in phase from liquid to vapor. Condenser 140 transfers heat from the cooling fluid, causing it to condense, thereby causing a change in phase from vapor to liquid. Evaporator 120 operates primarily on liquid, while condenser 140 operates primarily on vapor. It is seen, therefore, that the most efficient operation of device 100 occurs when evaporator 120 is mostly filled with liquid, while condenser 140 is mostly filled with vapor. Absent a control device such as check valve 146, however, gravity would equalize the level of liquid within each portion of assembly 100, namely evaporator 120 and condenser 140. For example, absent check valve 146, maintaining evaporator 120 mostly filled with liquid would result in condenser 140 being mostly filled with liquid, significantly reducing the efficiency of condenser 140. Similarly, absent check valve 146, maintaining condenser 140 mostly filled with vapor would result in evaporator 120 being mostly filled with vapor, significantly reducing the efficiency of evaporator 120. Check valve 146 provides a mechanism for maintaining a higher level of liquid in evaporator 120 than in condenser 140.

Check valve 146 may be any unidirectional valve as known in the art. Check valve 146 allows fluid flow in one direction only, from condenser tube 142 to boiling chamber 122 within evaporator 120, through inlet port 136. Check valve 146 preferably offers minimal resistance to fluid flow in the normal flow direction, and allows minimal to no fluid flow in the opposite direction. As shown in FIGS. 2 and 3, check valve 146 is a hinged flap, capable of opening toward boiling chamber 122 to allow normal fluid flow, and capable of sealing inlet port 136 against fluid flow from boiling chamber 122 to tube 142.

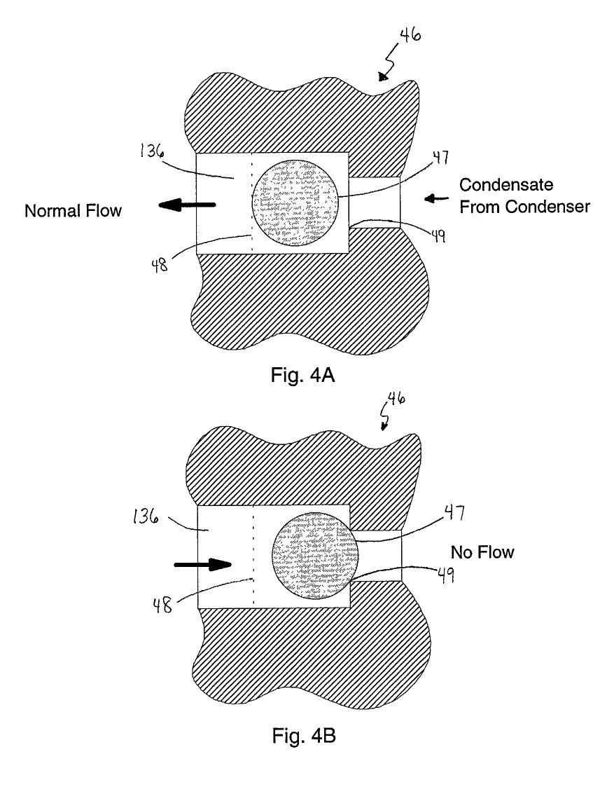

Alternative check valve embodiments are contemplated within the spirit and scope of the present invention. In particular, FIG. 4 illustrate check valve 46, using a lightweight ball 47. Ball 47 moves freely between stop 48 and stop 49, but cannot move beyond either stop. Stop 48 is located downstream of ball 47, assuming normal flow direction. Stop 48 is therefore located between ball 47 and boiling chamber 122. FIG. 4A illustrates check valve 46 during fluid flow in the normal direction, from condenser 140 to boiling chamber 122. As shown in FIG. 4A, during normal fluid flow ball 47 rests against stop 48. The diameter of ball 47 should be sufficiently smaller than the diameter of inlet port 36, allowing fluid flow around ball 47 during normal flow. Stop 48 should offer minimal resistance to normal fluid flow while preventing ball 47 from passing, and may be formed of a mesh screen or the like. Stop 49 is located upstream of ball 47, assuming normal flow direction. Stop 49 is therefore located between ball 47 and condenser 140. FIG. 4B illustrates check valve 46 during backflow. When fluid begins to flow backwards (i.e. from boiling chamber 122 to condenser 140), ball 47 moves toward and contacts stop 49. When in contact with stop 49, ball 47 and stop 49 form a fluid tight seal, preventing fluid flow from boiling chamber 122 into condenser 140.

The embodiments previously described sufficiently enable gravity induced fluid flow when module 110 is oriented vertically or nearly vertically. Alternative embodiments are envisioned wherein module 110 is tilted somewhat from vertical, within the spirit and scope of the present invention. Gravity induced fluid flow in such an alternative embodiment is assisted through the tube design of condenser 440 of cooling unit 400, as illustrated in FIG. 7. Condenser tube 442 is pitched slightly from horizontal, providing a sloping fluid flow path throughout. By providing a sloping fluid flow path, gravity induced fluid flow is enabled as module 110 is tilted in either direction away from vertical.

Materials and Construction Methods

Evaporator 120 should be constructed from an impermeable material having high thermal conductivity, such as copper or aluminum. To form the structure of internal boiling chamber 122, evaporator 120 is preferably formed of two pieces, such as boiling chamber portion 121a and cover 121b. Boiling chamber portion 121a may be formed by any means known in the art, such as by mold or a milling operation. In embodiments using an evaporator such as evaporator 120, having a nondivergent boiling chamber, cover 121a is substantially flat, and also includes holes for inlet and outlet ports 136 and 137, respectively. Boiling chamber portion 121a and cover 121b may be joined to form evaporator 120 by any methods known in the art, such as soldering, brazing, epoxy, or mechanical fasteners such as bolts and a gasket or O-ring.

FIG. 3 illustrates an alternative embodiment, evaporator 220, having boiling chamber portion 221a and cover 221b. The construction methods described with respect to evaporator 120 should be slightly modified if any of the optional performance enhancements of the evaporator embodiment 220 illustrated in FIG. 3 are employed. For example, extended heat transfer surfaces 252 and vapor deflectors 254 should be formed of impermeable materials having high thermal conductivity. Surfaces 252 may be formed separately and bonded to boiling surface 224 by any methods known in the art, such as by soldering or a thermally enhanced epoxy. Alternatively, surfaces 252 may be formed as part of boiling chamber portion 221a, during the mold or milling process used to form boiling chamber portion 221a. Vapor deflectors 254 are preferably movably mounted on boiling surface 224, such as with a hinge. Formation of a divergent boiling chamber such as boiling chamber 222 illustrated in FIG. 3 is preferably accomplished by modifying cover 221b, such that cover 221b is thicker in the lower region of boiling chamber 222 than in the upper region of boiling chamber 222, creating a surface 226 which diverges from boiling surface 224.

With reference again to FIG. 2, the materials and construction methods used to fabricate condenser section 140 are discussed. The materials and construction methods used to fabricate condenser 140 are well known in the art of tube/fin heat exchanger design and manufacture. Tubes 142 are constructed of impermeable materials having high thermal conductivity, such as copper or aluminum. Tubes 142 are preferably fabricated using straight tube sections and fitted elbows, to provide easier assembly of condenser 140 as described in detail herein. Fins 144 are constructed of thin plates of material having high thermal conductivity, such as copper or aluminum. Condenser 140 may be assembled by first arranging an array of straight tube sections, in accordance with the locations of inlet and outlet ports 136 and 137 within evaporator 120. Holes are drilled or stamped in fins 144 in the locations where tubes 142 are to be inserted. Fins 144 are placed over the arranged array of tubes 142, maintaining spaces between adjacent fins 144. When all fins 144 are placed upon the tube array, appropriate ends of tubes 142 are joined at each end of the stack of fins 144, using a connector such as a fitted elbow. The elbows are joined to the straight tube sections, forming an air tight tube. Tubes 142 and elbows may be joined by any methods known in the art capable of producing air and liquid tight joints, such as by soldering or brazing. The inlet and outlet ends of each tube 142 are then connected to a source of high pressure gas such as air, and tubes 142 are pressurized. The high internal pressure causes tubes 142 to expand, forming a mechanical joint with fins 144. Alternatively, fins 144 may be metallurgically bonded to tubes 142, such as by soldering or brazing. Finally, condenser 140 is joined to evaporator 120 by connecting tubes 142 to inlets and outlets 136 and 137, such as by soldering, brazing, or by using liquid-tight fittings as known in the art.

The construction methods described with respect to condenser 140 should be modified slightly for the embodiment illustrated in FIG. 7, condenser 440. As previously described, condenser 440 includes tubes 442 which are pitched slightly to improve the flow of fluid within tubes 442. This optional feature is especially useful if module 110 is tilted somewhat from vertical. The pitch of tubes 442 causes each tube 442 to intersect fins 444 at different locations within the fins, unlike evaporator 140 where each tube 142 intersects all fins 144 at the same location within each fin. A variety of alternative construction methods may be used to construct evaporator 440. For example, fins 444 may be constructed with slightly elliptical holes, sufficient to accommodate tube 442 intersecting at an angle. When using this construction method, each fin 444 includes a unique pattern of holes, determined by its position within evaporator 440. The entire array of fins is assembled first, spaced appropriately, thereby creating pitched channels into which straight tube sections are passed. Once the tube sections are inserted through the fin structure, the tube ends are joined using elbows and the entire unit is pressurized as described with respect to evaporator 140. Alternatively, fins 444 could be constructed using holes which are elongated in the direction of tube 442 pitch. The holes should be sufficiently elongated such that fins 444 fit over an array of tubes 442 at any location along the array of tubes. Such elongated holes permit the use of a construction method similar to that described with respect to evaporator 140: straight sections of tubes 442 are first arranged, then fins 444 are assembled by sliding them over tubes 442, elbows are joined to the straight sections of tubes 442, then the assembly is pressurized. Of these exemplary construction methods, the first method, using slightly elliptical holes, provides superior performance by maximizing thermal contact between fins 444 and tubes 442. The second method, using elongated holes, offers reduced complexity (all fins 444 are identical) and possibly reduced fabrication cost, however the elongated holes reduce thermal contact between fins 444 and tubes 442.

Once assembly 100 is constructed as described, a cooling fluid is introduced into boiling chamber 122. Any cooling fluid known in the art may be used, such as refrigerants or other dielectric fluids, water, brine, or other aqueous fluids. The superior thermal conductivity and specific heat properties of water, however, make water a preferred cooling fluid choice.

FIG. 5A depicts a top view of evaporator 120, illustrating the placement of filling valve 600. As shown in FIG. 5A, filling valve 600 is located along a side edge of evaporator 120, and opens into boiling chamber 122. As previously noted, once assembly 100 is constructed, a cooling fluid may be introduced into boiling chamber 122. As further described herein, in some applications it may be desirable to create a low pressure environment within boiling chamber 122, in order to reduce the temperature at which fluid 50 boils. Filling valve 600 may be used for this purpose.

With reference now to FIGS. 5B through 5D, the operation of filling valve 600 is now described. As shown in FIG. 5B, filling valve 600 includes valve body 602, spring 604, boiling chamber port 606, external port 608, valve seat 610, and threaded casing 607. FIG. 5B depicts valve 600 after final assembly of cooling assembly 100. In this state, spring 604 presses valve seat 610 against the angled sides of valve body 602, thereby sealing off external port 608. FIG. 5C depicts valve 600 during the process of evacuating air from and introducing fluid into apparatus 100. Filling device 609 includes a threaded portion, engageable with threaded casing 607. Device 609 further includes seal 603a, such as a gasket or O-ring. During the evacuation and fill process, device 609 is threaded into casing 607, engaging seal 603a against evaporator 120, thereby creating an air and liquid tight seal. Device 609 includes projection 601, which depresses valve seat 610, thereby opening external port 608. Device 609 should be designed such that seal 603a sealably engages evaporator 120 before projection 601 begins to depress valve seat 610. In the position shown in FIG. 5C, a vacuum is applied to device 609, evacuating air from within boiling chamber 122. While maintaining vacuum, cooling fluid is introduced into boiling chamber 122, preferably at a pressure below atmospheric pressure. Once the desired pressure of cooling fluid is introduced, device 609 is removed from valve 600, returning valve 600 to the state illustrated in FIG. 5B. When device 100 contains fluid at subatmospheric pressure, the pressure differential between boiling chamber 122 and the ambient exerts a force upon valve seat 610. Spring 604 should exert sufficient force to sealably engage seat 610 against valve body 602 given the force exerted by the pressure differential. During device 609 removal, seal 603a should remain sealably engaged against evaporator 120 until valve seat 610 seals external port 608. Finally, plug 605 is inserted into threaded casing 607. Plug 605 includes seal 603b, which sealably engages evaporator 120, thereby preventing ingress of ambient air into boiling chamber 122. Plug 605 and seal 603b provide a higher quality and more permanent seal than the temporary seal provided by valve seat 610.

As previously noted, the cooling apparatus of the present invention transfers heat from devices 114 to the ambient air by boiling a cooling fluid within boiling chamber 122, and condensing the fluid within condenser 140. Also as previously noted, the rate of heat transfer from device 114 to boiling surface 124 depends upon the temperature differential between device 114 and boiling surface 124. For a specific temperature differential between boiling surface 124 and device 114, and therefore a specific rate of heat transfer and a specific device 114 power dissipation, a decrease in the temperature of boiling surface 124 results in a corresponding decrease in the temperature of device 114. Alternatively, for a specific device 114 temperature, a lower boiling surface 124 temperature results in a corresponding increase in temperature differential between boiling surface 124 and device 114, increasing heat transfer and enabling increased device 114 power dissipation while maintaining constant device 114 temperature. It is seen, therefore, that reducing the temperature of boiling surface 124, and therefore the boiling temperature of fluid 50, is desirable in some embodiments. For example, in applications using a dielectric cooling fluid, the specific dielectric fluid used may be selected from a variety of possible dielectric fluids, based at least in part upon the fluid boiling temperature at atmospheric pressure. Proper selection of a dielectric fluid, therefore, may provide a lower boiling surface 124 temperature, while maintaining the cooling fluid at or above atmospheric pressure. For many applications, however, water is a preferred fluid due to its superior properties, namely heat of vaporization, thermal conductivity, and specific heat. Water boils at 100° C. at atmospheric pressure; if a lower boiling surface 124 temperature is desired, the pressure within boiling chamber 122 should be reduced. A preferred application of the present invention provides a lower boiling surface 124 temperature, using water as a cooling fluid. As previously noted with respect to FIGS. 5B through 5D, filling valve 600 may be used to evacuate air from within device 100, and introduce a cooling fluid such as water. By evacuating air and introducing enough water to completely fill boiling chamber 122, the lowest possible water boiling temperature is achieved. The actual temperature at which water within boiling chamber 122 boils depends upon a number of factors, including the extent to which air is evacuated, the condenser temperature, the ambient air temperature, and the heat load from module 110.

Integrated Embodiments

Alternative embodiments are envisioned within the spirit and scope of the present invention. In particular, two alternative embodiments employing an integrated module and cooling unit are described in detail herein. These alternative embodiments do not offer the field replacement capabilities of the embodiments illustrated in FIGS. 2 through 3, however the alternative embodiments offer performance advantages by reducing the thermal path between the electronic devices to be cooled and the cooling fluid.

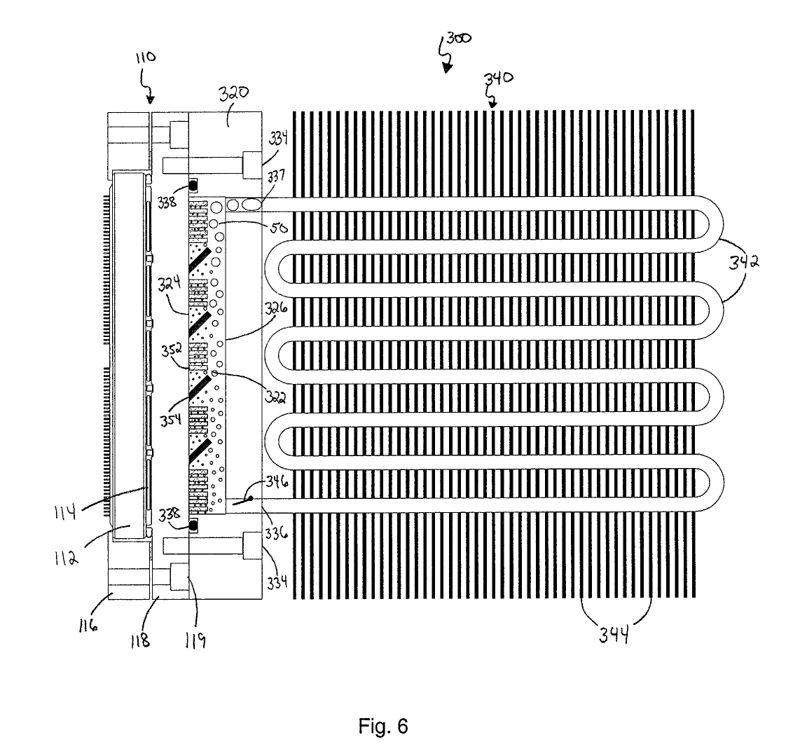

FIG. 6 illustrates an integrated module and cooling assembly 300, per an embodiment of the present invention. As previously described, module assembly 110 includes substrate 112, devices 114, base plate 116, module hat 118, and connectors 119. Evaporator 320 includes boiling chamber 322. Unlike the embodiment of FIGS. 2 through 3, one surface of boiling chamber 322, namely boiling surface 324, is formed by the upper surface of module hat 118. Evaporator 320 is connected to hat 118 by connectors 324, which compress seal 338, thus forming a liquid tight seal. Seal 338 may be a gasket or o-ring, as known in the art. As described with respect to the embodiment of FIGS. 2 through 3, evaporator 320 of the embodiment of FIG. 6 includes boiling chamber 322, boiling surface 324, boiling chamber surfaces 326, 328 (bottom), and 330 (top), inlet port 336, outlet port 337, and check valve 346. As described with respect to the embodiment of FIGS. 2 through 3, condenser 340 of the embodiment of FIG. 6 includes tubes 342 and fins 344. The embodiment of FIG. 6 functions in the same manner as previously described with respect to the embodiment of FIGS. 2 through 3.

As noted, the primary difference between assembly 300 of FIG. 6 and assembly 100 of FIGS. 2 through 3 is boiling surface 324. By eliminating the boiling surface portion of evaporator 100, evaporator 300 places cooling fluid 50 in direct thermal contact with module hat 118, thereby improving the flow of heat from devices 114 to cooling fluid 50. Furthermore, the open design of evaporator 320 enables its construction as a single section. Evaporator 320 is constructed using the same material choices and fabrication methods discussed with respect to evaporator 120.

As in the embodiment of FIGS. 2 through 3, optional performance enhancements may be used with the embodiment of FIG. 6. In particular, optional extended heat transfer surfaces 352 are mounted directly to module cap 118, since the upper surface of cap 118 is now boiling surface 324. Similarly, optional vapor deflectors 354 are mounted to the upper surface of cap 118. Finally, a divergent boiling chamber may be created by modifying surface 326 such that it diverges from boiling surface 324 along the direction of fluid flow, as illustrated in the embodiment of FIG. 3.

FIG. 7 illustrates assembly 400, per an embodiment of the present invention. Evaporator 320 and module 110 are unchanged from the embodiment illustrated in FIG. 6. As previously noted, condenser 440 employs pitched tubes 442, enabling gravity driven fluid flow while assembly 400 is tilted somewhat from vertical.

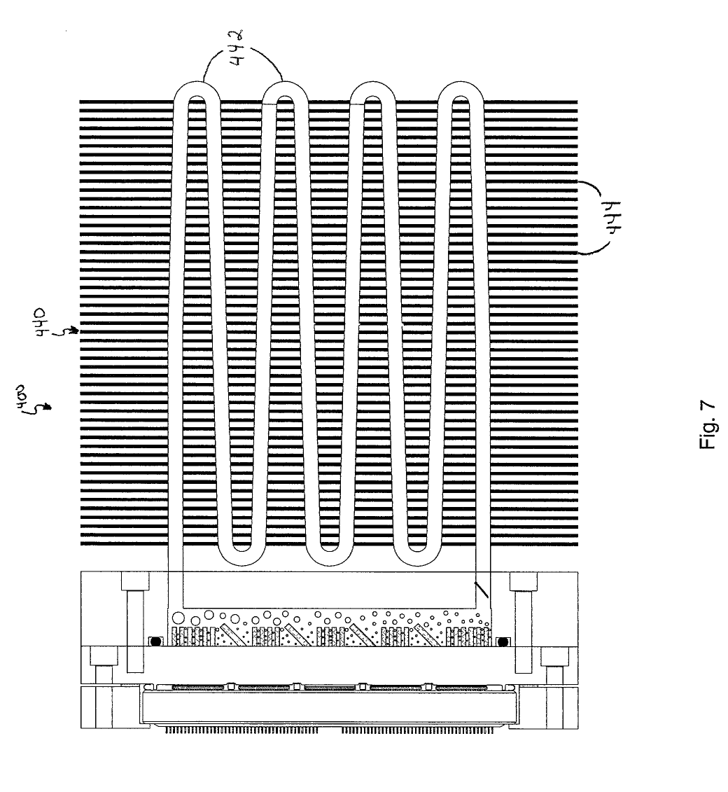

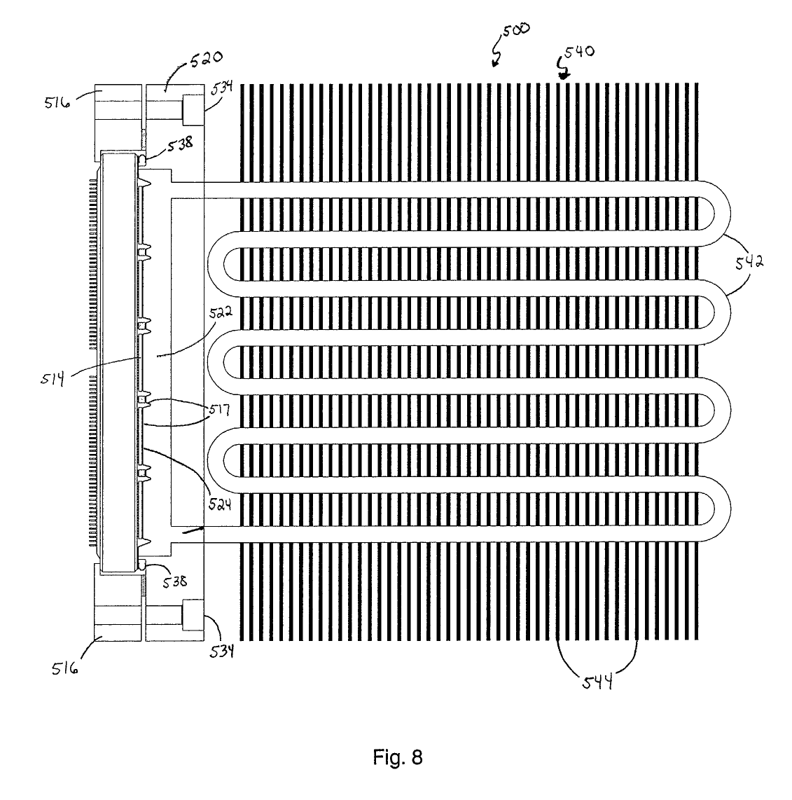

FIG. 8 illustrates integrated module and cooling assembly 500, per yet another embodiment of the present invention. The embodiment of FIG. 8 further improves upon the heat transfer characteristics of the embodiment illustrated in FIGS. 6 and 7, by further reducing the thermal path between devices 114 and cooling fluid 50. Module hat 118 of the embodiments depicted in FIGS. 2 through 3, 6, and 7, is no longer present in assembly 500. Evaporator 520 is now connected directly to base plate 516 by connectors 534. Evaporator 520 is constructed using the same material choices and fabrication methods discussed with respect to evaporators 120 and 320. Seal 538, such as a gasket or O-ring, provides a liquid-tight seal around the perimeter of boiling chamber 522. The embodiment illustrated in FIG. 8 employs barrier 517 over devices 514. Such a barrier is described in a co-filed and commonly owned patent application, attorney docket number POU9-2001-0135, Ser. No.______, which is hereby incorporated herein by reference in its entirety. In the embodiment of FIG. 8, cooling assembly 500, barrier 517 is now boiling surface 524. Barrier 517, therefore, provides a low thermal resistance path between devices 514 and a fluid within boiling chamber 522, while preventing direct contact between devices 514 and a cooling fluid. The embodiment illustrated in FIG. 8 results in a significant reduction in the thermal path between devices 514 and a cooling fluid, compared to either the embodiment of FIGS. 6 and 7 or the embodiment of FIGS. 2 through 3. Alternatively, if a dielectric fluid is used within boiling chamber 522, barrier 517 may be entirely eliminated.

Cooling Subassembly

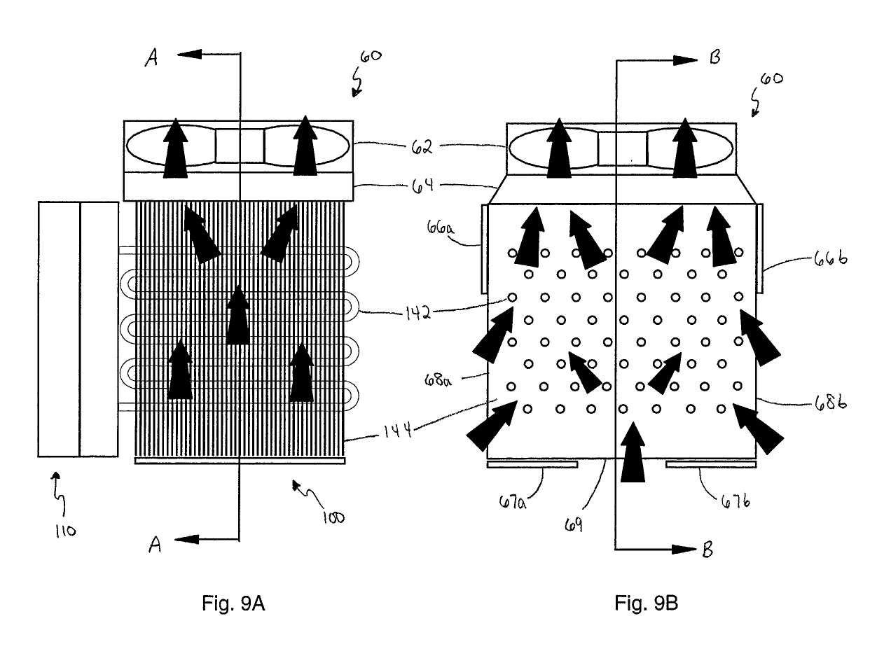

The various embodiments of the cooling apparatus and electronic module assembly of the present invention may be incorporated into a larger cooling assembly, within the spirit and scope of the present invention. FIGS. 9A and 9B illustrate cooling assembly 60, incorporating one of many possible embodiments of a module and cooling assembly, such as assembly 100, per the present invention. In addition to elements contained within assembly 100, cooling assembly 60 contains one or more air moving devices 62, plenum 64, side baffles 66a and 66b, bottom baffles 67a and 67b, side air inlets 68a and 68b, and bottom air inlet 69. Device 62 may be any suitable air moving device, such as a fan or blower. Plenum 64 collects air flowing through condenser fins 144, and directs the collected air to air moving device 62. Side baffles 66a and 66b, along with bottom baffles 67a and 67b, reduce the air temperature differential between the bottom and top of condenser 140. Since fins 144 are at a higher temperature than the ambient air, fins 144 transfer heat to the air as the air passes through and over fins 144. Air entering through bottom air inlet 69 tends to rise in temperature as it traverses fins 144. By using side and bottom baffles 66a, 66b, 67a, and 67b, cooler air is allowed to enter through side air inlets 68a and 68b and flow over the upper portions of fins 144 without having been in contact with the lower portions of fins 144.

Cooling assembly 60, as illustrated in FIGS. 9A and 9B, may constitute a field replaceable cooling unit. As shown using cooling assembly 100, the entire assembly 60 may be separated from module 110 in the field and replaced, without removing module 110. Alternative embodiments are envisioned wherein a integrated cooling assembly is used, such as assembly 300. When an embodiment such as assembly 300 is used within cooling assembly 60, electronic module 310 must be removed and replaced as well as cooling assembly 60.

Environment

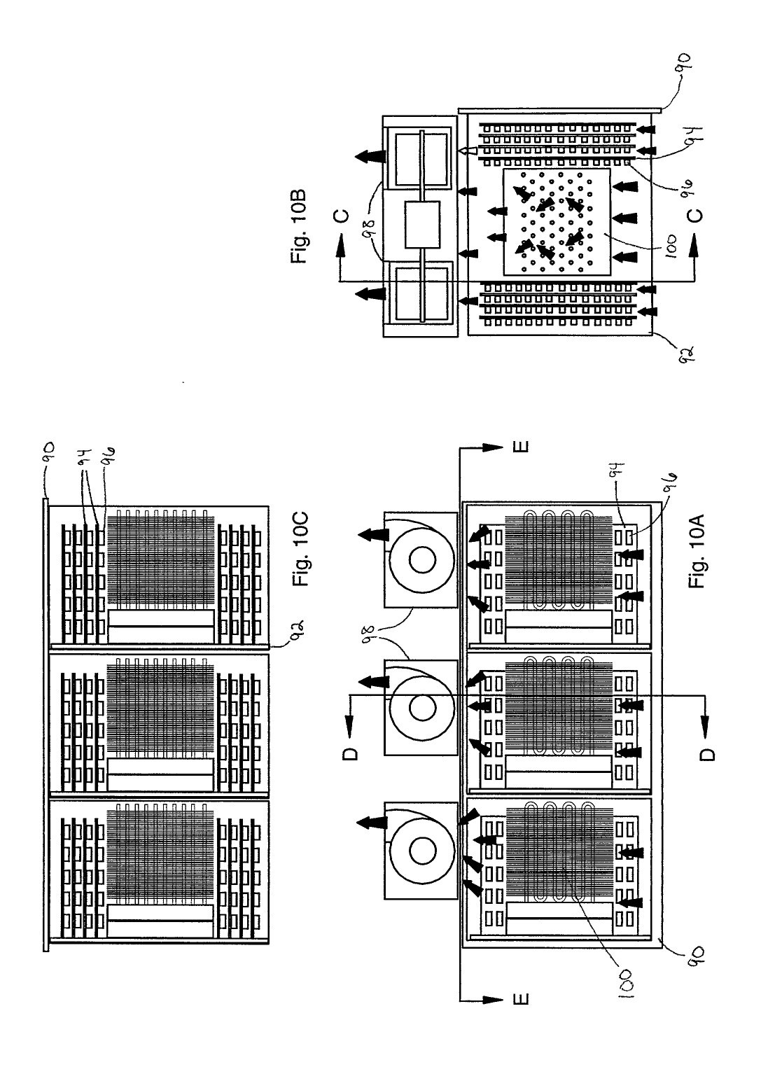

In systems with multiple processor modules, cooled module assemblies per the present invention may be packaged in a “book” configuration as illustrated in FIGS. 10. In this configuration, the electronic module assembly 100 is mounted on daughter board 92 along with arrays of other lower power components, such as memory components 96 mounted on printed circuit cards 94. One or more daughter boards 92 are plugged into motherboard 90, and may be supported by a suitable cage or other mechanical structure (not illustrated). Air moving devices 98 are mounted are mounted above the book or daughter board assemblies, providing cooling airflow over the module assemblies 100 and cards 94. Plates with a suitable array of orifice openings may be placed at the bottom of each book assembly to appropriately apportion the flow of cooling air over the module assembly 100 and cards 94.

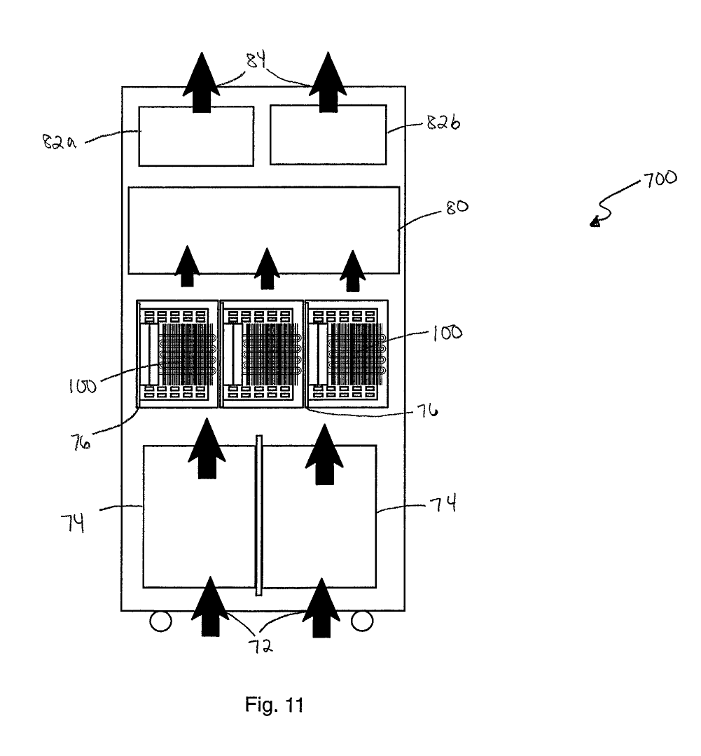

An alternative system level cooling arrangement is illustrated in FIG. 11. The overall arrangement of system 700 is similar to the arrangement of system 70 illustrated in FIG. 1, with the exception of modules 78. In the embodiment of FIG. 11, modules 78 of FIG. 1 are replaced by an embodiment of a cooled module assembly per the present invention, such as assembly 100. As discussed with reference to FIG. 1, in system 700 of FIG. 11 air flows from inlet 72, over cards 74, over module assemblies 100 mounted on board 76, through power compartment 80, driven by blowers 82a and 82b, finally exiting cabinet 70 through exhaust outlet 84. The arrangement of systems 70 and 700, as illustrated in FIGS. 1 and 11 respectively, have the advantage that a single set of blowers 82a and 82b provide cooling airflow to the entire system 70 or 700. By replacing modules 78 with an embodiment of the present invention such as assembly 100, enhanced air cooling of high power components such as devices 114 within module 110 is provided by assembly 100 within the space and airflow constraints of system 700.

While the invention has been described in detail herein in accord with certain preferred embodiments thereof, many modifications and changes therein may be effected by those skilled in the art. Accordingly, it is intended by the appended claims to cover all such modifications and changes as fall within the true spirit and scope of the invention.

What is claimed is:

1. A cooling apparatus for an electronic module, said electronic module having a substantially vertical orientation, said cooling apparatus comprising:
an evaporator with a surface for making thermal contact with said electronic module;
a boiling chamber within said evaporator, said boiling chamber having a plurality of fluid inlet ports disposed proximate one end of said boiling chamber, said boiling chamber having a plurality of fluid outlet ports disposed proximate an opposing end of said boiling chamber; and
a condenser having a plurality of tubes, each of said plurality of tubes being in fluid flow communication with one of said plurality of fluid outlet ports and one of said plurality of fluid inlet ports, said condenser further having a heat exchanger, said heat exchanger having a plurality of thermally conductive fins, each of said plurality of fins being in thermal contact with one or more of said plurality of tubes;
a plurality of check valves, each of said check valves being disposed within a fluid flow path in proximity to one of said boiling chamber inlet ports, each of said check valves being oriented to allow fluid flow from said tube to said boiling chamber while prohibiting fluid flow from said boiling chamber into said tube.

2. The apparatus of claim 1, further comprising a cooling fluid.

3. The apparatus of claim 2, wherein said cooling fluid is selected from the group consisting of water, brine, and dielectric fluids.

4. The apparatus of claim 3, wherein said dielectric fluid is a refrigerant.

5. The apparatus of claim 2, wherein said cooling fluid is at a pressure below atmospheric pressure.

6. The apparatus of claim 1, further comprising one or more extended heat transfer surfaces in thermal contact with said evaporator surface for making thermal contact with said electronic module.

7. The apparatus of claim 6, further comprising one or more vapor deflectors disposed proximate at least one of said one or more extended heat transfer surfaces.

8. The apparatus of claim 1, wherein said boiling chamber edges are rounded in shape.

9. The apparatus of claim 1, wherein the thickness of said boiling chamber is greater near said fluid outlet ports than near said fluid inlet ports.

10. The apparatus of claim 2, wherein said plurality of tubes are pitched to improve gravity induced flow of said cooling fluid when said electronic module is oriented other than vertically.

12. A fluid-cooled electronic apparatus, comprising:
an electronic module, said electronic module having a substantially vertical orientation;
an evaporator in thermal contact with said electronic module;
a boiling chamber within said evaporator, said boiling chamber having a plurality of fluid inlet ports disposed proximate one end of said boiling chamber, said boiling chamber having a plurality of fluid outlet ports disposed proximate an opposing end of said boiling chamber;
a condenser comprising a plurality of tubes, each of said plurality of tubes being in fluid flow communication with one of said plurality of fluid outlet ports and one of said plurality of fluid inlet ports, said condenser further comprising a heat exchanger, said heat exchanger comprising a plurality of thermally conductive fins, each of said plurality of fins being in thermal contact with one or more of said plurality of tubes;
a plurality of check valves, each of said check valves being disposed within a fluid flow path in proximity to one of said boiling chamber inlet ports, each of said check valves being oriented to allow fluid flow from said tube to said boiling chamber while prohibiting fluid flow from said boiling chamber into said tube.

13. The apparatus of claim 12, further comprising a cooling fluid.

14. The apparatus of claim 12, wherein said cooling fluid is selected from the group consisting of water, brine, and dielectric fluids.

15. The apparatus of claim 12, wherein said dielectric fluid is a refrigerant.

16. The apparatus of claim 12, wherein said cooling fluid is at a pressure below atmospheric pressure.

17. The apparatus of claim 12, further comprising one or more extended heat transfer surfaces in thermal contact with said evaporator surface for making thermal contact with said electronic module.

18. The apparatus of claim 17, further comprising one or more vapor deflectors disposed proximate at least one of said one or more extended heat transfer surfaces.

19. The apparatus of claim 12, wherein said boiling chamber edges are rounded in shape.

20. The apparatus of claim 12, wherein the thickness of said boiling chamber is greater near said fluid outlet ports than near said fluid inlet ports.

21. The apparatus of claim 12, wherein said electronic module is oriented other than horizontally.

22. The apparatus of claim 12, wherein said evaporator and condenser form a unit, said unit being detachable from said electronic device.

23. The apparatus of claim 12, wherein said cooling fluid is in substantially direct thermal contact with said electronic module.

25. A cooling assembly for an electronic module, said cooling assembly comprising:
an evaporator with a surface for making thermal contact with said electronic module;
a boiling chamber within said evaporator, said boiling chamber having a plurality of fluid inlet ports disposed proximate one end of said boiling chamber, said boiling chamber having a plurality of fluid outlet ports disposed proximate an opposing end of said boiling chamber;
a condenser comprising a plurality of tubes, each of said plurality of tubes being in fluid flow communication with one of said plurality of fluid outlet ports and one of said plurality of fluid inlet ports, said condenser further comprising a heat exchanger, said heat exchanger comprising a plurality of thermally conductive fins, each of said plurality of fins being in thermal contact with one or more of said plurality of tubes;
a plurality of check valves, each of said check valves being disposed within a fluid flow path in proximity to one of said boiling chamber inlet ports, each of said check valves being oriented to allow fluid flow from said tube to said boiling chamber while prohibiting fluid flow from said boiling chamber into said tube;
an air moving device, capable of causing air to flow through said condenser;
a plurality of baffles, capable of directing airflow through said condenser.

26. The assembly of claim 25, further comprising a cooling fluid.

27. The assembly of claim 26, wherein said cooling fluid is selected from the group consisting of water, brine, and refrigerant.

28. The assembly of claim 26, wherein said cooling fluid is at a pressure below atmospheric pressure.

29. The assembly of claim 25, wherein said plurality of baffles form a plurality of air inlets.

30. The assembly of claim 29, wherein said plurality of air inlets are distributed along the direction of airflow through said condenser.

31. The assembly of claim 25, further comprising a plurality of check valves, each of said check valves being disposed within a fluid flow path in proximity to one of said boiling chamber inlet ports, each of said check valves being oriented to allow fluid flow from said tube to said boiling chamber while prohibiting fluid flow from said boiling chamber into said tube.
